(19) United States
(12) Patent Application Publication
(10) Pub. No.: US 2018/0202037 A1
(43) Pub. Date: Jul. 19, 2018

(54) SILVER NANO-METAL MESH INCLUSIVE ELECTRODE, TOUCH PANEL WITH SILVER NANO-METAL MESH INCLUSIVE ELECTRODE, AND/OR METHOD OF MAKING THE SAME

(71) Applicant: Guardian Glass, LLC, Auburn Hills, MI (US)

(72) Inventors: Jason BLUSH, Milford, MI (US); Patricia TUCKER, Lambertville, MI (US)

(21) Appl. No.: 15/890,633

(22) Filed: Feb. 7, 2018

Related U.S. Application Data
(63) Continuation-in-part of application No. 15/855,343, filed on Dec. 27, 2017.
(60) Provisional application No. 62/456,409, filed on Feb. 8, 2017.
(60) Provisional application No. 62/440,490, filed on Dec. 30, 2016.

(51) Int. Cl. C23C 14/18; C23F 1/00; C23C 14/34; C23C 14/58; C23C 14/02; C23C 14/16

(52) U.S. Cl. CPC C23C 14/185; C23F 1/00; C23C 14/34; G06F 3/044; C23C 14/022; C23C 14/024; C23C 14/165; C23C 14/5806

(57) ABSTRACT

Certain example embodiments relate to silver nano-metal mesh inclusive electrodes, and/or methods of making the same. The techniques described herein may be used, for example, in projected capacitive touch panels, display devices, and/or the like. Purposeful de-wetting of physical vapor deposited (PVD) silver (e.g., sputter deposited silver) is used to create the mesh. The properties of the mesh can be controlled through heat treatment, changes to the base layer composition (e.g., using materials with different surface energies, or adjusting surface energies), the creation of non-Ag PVD or otherwise formed islands that act as nodes for the film to attach itself to during the de-wetting process, and/or the like.

### CROSS-REFERENCE TO RELATED APPLICATION

This application claims the benefit of U.S. application Ser. No. 62/456,409 filed on Feb. 8, 2017, the entire contents of which is hereby incorporated herein by reference. This application also is a continuation-in-part (CIP) of U.S. application Ser. No. 15/855,343 filed on Dec. 27, 2017, which claims the benefit of U.S. application Ser. No. 62/440,490 filed on Dec. 30, 2016, the entire contents of each of which is hereby incorporated herein by reference.

### FIELD OF THE INVENTION

Certain example embodiments of this invention relate to electrodes for use in touch panels, and/or methods of making the same. More particularly, certain example embodiments of this invention relate to silver nano-metal mesh inclusive electrodes, and/or methods of making the same. The techniques described herein may be used, for example, in projected capacitive touch panels and/or the like.

### BACKGROUND AND SUMMARY

ITO (indium tin oxide) typically is viewed as the de facto material for creating conductive layers. ITO has been used for a number of different purposes, in a variety of display technologies including, for example, as common electrodes and in forming thin-film transistors (TFTs) in liquid crystal display (LCD) devices. ITO also has been used in various types of touch panels and is currently believed to be regarded as the most likely candidate for use in conductive layers used in projected-capacitive touch technology.

Despite the widespread usage of ITO, the display and electronics industries have been looking to replace ITO. Indeed, there has been a desire to increase performance (e.g., increased transmissivity and decreased resistivity) while lowering material and process-related costs (e.g., related at least in part to the limited supply of indium in the world). Because of these considerations, ITO has not achieved widespread usage in projected-capacitive touch technology, especially when large size applications are involved. A number of different ITO replacements are in development, and some are even commercially available. Potential ITO replacements include metal meshes, silver nanowires, carbon nanotubes, conductive polymers, graphene, and the like.

Although these candidate replacements offer promise, the search for a good performing, low cost electrode material and/or fabrication technique is ongoing. Certain example embodiments address these and/or other concerns. For example, certain example embodiments relate to high transmission, low resistivity, and low-cost electrodes and/or methods of making the same. These electrodes may be used in touch panels including, for example, projected capacitive touch panels that are large in size, as well as resistive and capacitive type touch panels, display devices, and/or the like.

In certain example embodiments, a method of making an electronic device is provided, with the method comprising: forming a thin film underlayer, directly or indirectly, on a substrate; sputter-depositing silver directly on and in contact with the underlayer; heating the sputter-deposited silver to a temperature and for a time sufficient to cause the silver to at least partially de-wet and form a nano-mesh comprising silver wires and pores, with the underlayer having a surface energy facilitating the at least partial de-wetting of the silver and the formation of the nano-mesh; and building the substrate with the nano-mesh formed thereon into the electronic device.

In certain example embodiments, a similar method may be used to form an electrode.

In certain example embodiments, electronic devices (e.g., touch panels, displays, etc.) made using these techniques are provided.

The features, aspects, advantages, and example embodiments described herein may be combined to realize yet further embodiments.

### BRIEF DESCRIPTION OF THE DRAWINGS

These and other features and advantages may be better and more completely understood by reference to the following detailed description of exemplary illustrative embodiments in conjunction with the drawings, of which:

FIG. 1 includes images of a sequence in which silver is deposited as an opaque liquid and is dried to form a metal-mesh film;

FIGS. 2A-2F show typical stages in creating a droplet or agglomerate;

FIGS. 3A-3C show successive morphological changes during de-wetting relevant in ultrathin polyethyleneoxide (PEO) polymer films;

FIGS. 4A-4C is a set of SEM images showing what happens to gold nanoparticles after heat treatment;

FIG. 5 is a flowchart showing an example process for forming a silver nano-mesh usable in connection with certain example embodiments; and

FIG. 6 is a cross-sectional view of a coated article made in accordance with certain example embodiments.

### DETAILED DESCRIPTION

Certain example embodiments relate to silver nano-metal mesh inclusive electrodes, and/or methods of making the same, which may be used, for example, in projected capacitive touch panels, display devices, and/or the like.

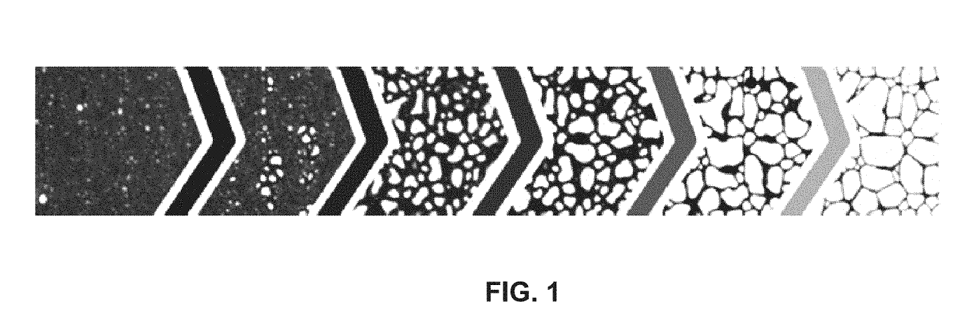

As mentioned above, metal meshes have been considered one possible way to provide transparent electrodes. One variation on the metal mesh concept involves applying a liquid coating on a film. When the film dries, a random pattern silver mesh is created. Cima NanoTech, for example, has developed a “self-assembling” silver mesh, made by providing an opaque liquid coating to a film using standard equipment and drying for about 30 seconds to create a randomly patterned silver mesh. FIG. 1 shows stages in this example drying sequence. Once formed, the mesh can be patterned via several methods.

Certain example embodiments create a similar random pattern of silver mesh through the sputtering of a silver film on a substrate. This technique takes advantage of the tendency of sputter-deposited silver to de-wet or agglomerate. Thus, certain example embodiments create a silver metal mesh through purposeful film de-wetting, e.g., in connection with a sputter-deposited thin film of or including silver or the like. As explained in greater detail below, the properties of the mesh can be controlled through heat treatment, changes to the base layer composition (e.g., using materials with different surface energies, adjusting surface energies, etc.), the creation of non-Ag physical vapor deposited (PVD) or otherwise formed islands that act as nodes for the film to attach itself to during the de-wetting process, and/or the like. Although de-wetting oftentimes is regarded as an undesired effect, certain example embodiments use techniques to control it and produce patterned or continuous films with desirable electro-optical properties. That is, certain example embodiments leverage the ability of PVD-deposited thin films to de-wet, which oftentimes is seen as disadvantageous and something to be avoided, to assist in the creation of a patterned or continuous film with desirable electro-optical properties.

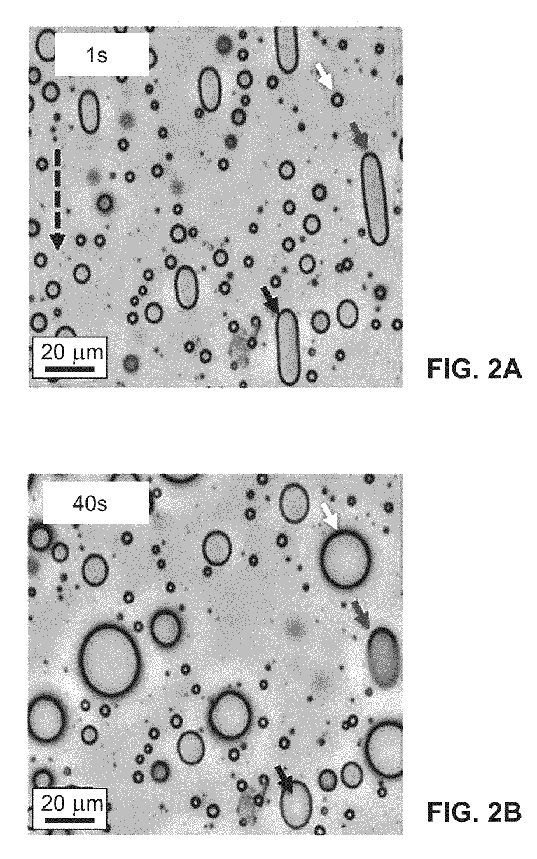

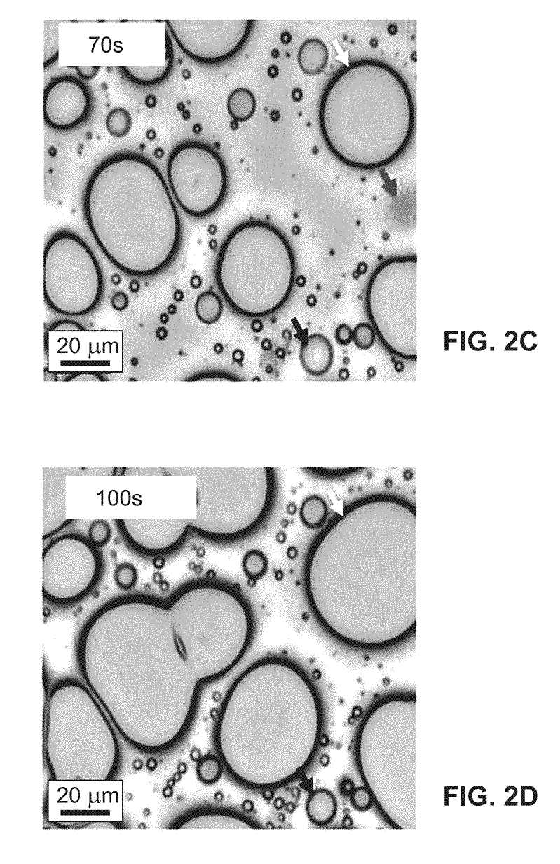

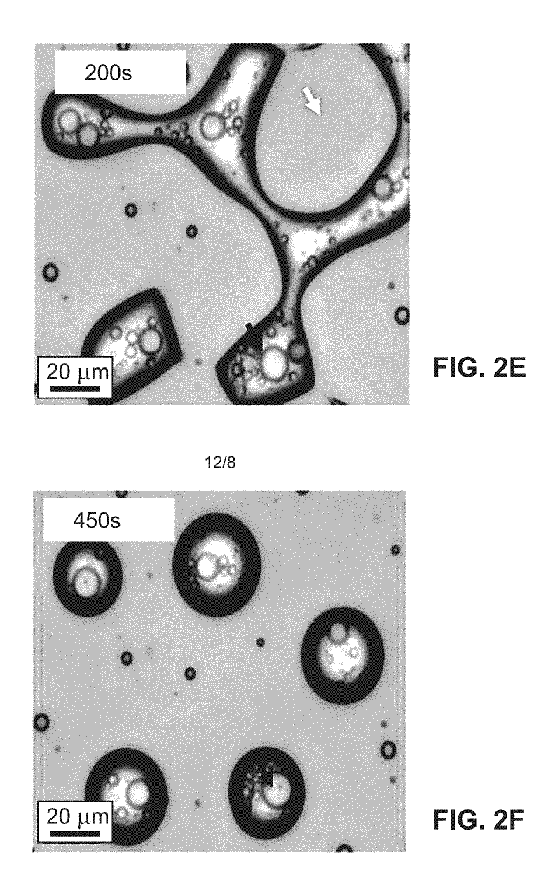

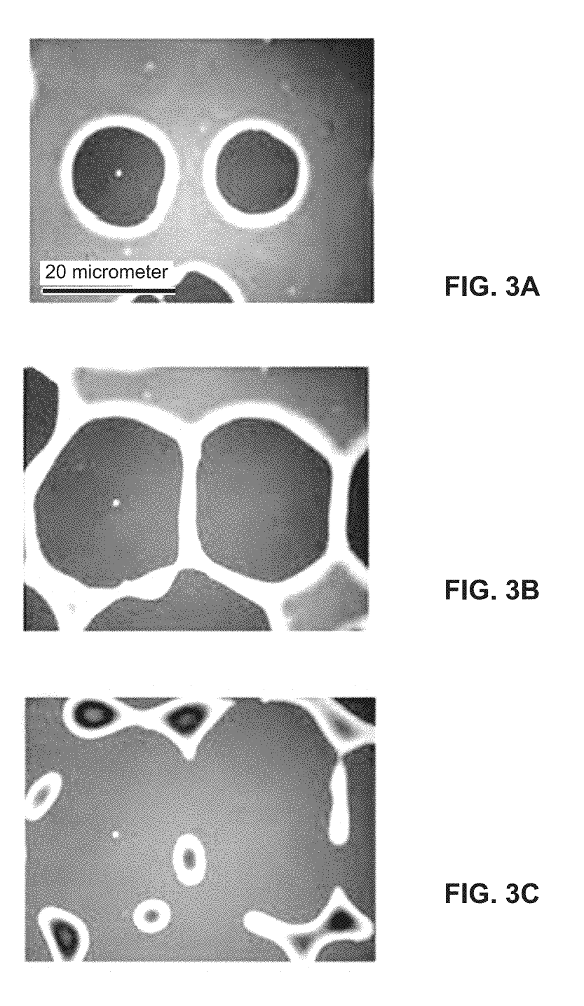

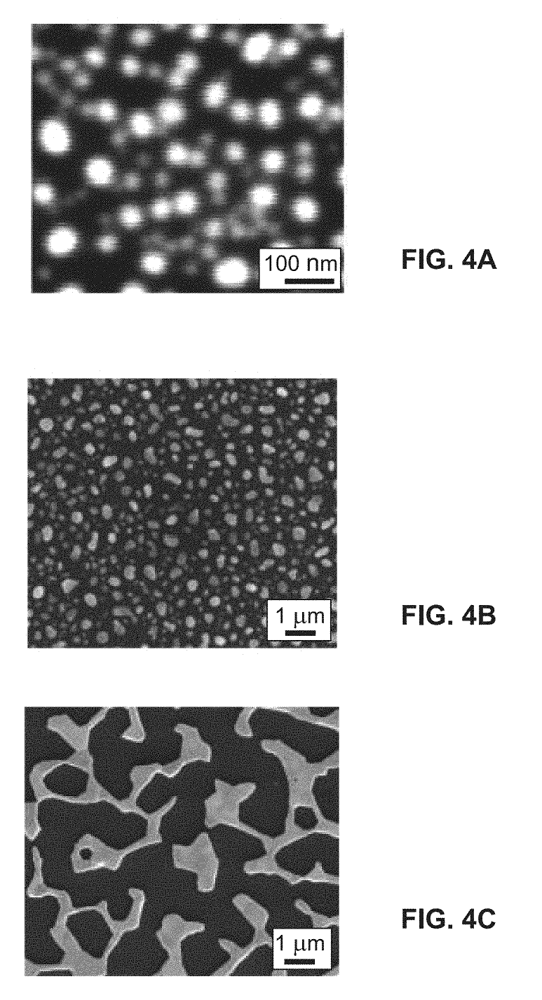

FIGS. 2A-4C help demonstrate how certain example embodiments operate. More particularly, FIGS. 2A-2F show typical stages in creating a droplet or agglomerate, as described in Y. J. Huang et al., “Formation and dynamics of coro-shell droplets in immiscible polymer blends,” RSC Advances, 2014, 4, 43150-43154. Similar stages are shown in FIGS. 3A-3C, described in Hans-Georg Braun and Evelyn Meyer, “Structure Formation of Ultrathin PEO Films at Solid Interfaces—Complex Pattern Formation by Dewetting and Crystallization,” Int. J. Mol. Sci. 2013, 14(2), 3254-3264, as well as in FIGS. 4A-4C, which includes SEM images of gold nanoparticles formed on the native oxide surface of Si[111] after annealing of Au films at 650 degrees C. for 1 hour deposited by sputtering for different lengths of time (left: 30 s; center: 1 min.; right: 2 min.) as described in Britta Kampken et al., “Directed deposition of silicon nanowires using neopentasilane as precursor and gold as catalyst,” Beilstein J Nanotechnol., 2012, 3, 535-545. The entire contents of each of these articles is hereby incorporated herein by reference.

As will be appreciated from the above, there are three basic stages in the formation of a droplet. These stages include hole initiation, hole growth, and rupture or droplet formation. During the hole growth phase, there is a period of time where a continuous network of material exists. Certain example embodiments include the sputtering of a silver thin film on a base layer that promotes the growth of holes, and then eventually droplets, to create a random silver mesh. The network of holes can be controlled to affect hole size, overall porosity, and/or the like. One or more of the following and/or other techniques may be used in this regard: (1) heating; (2) base layer composition selection and/or adjustment; and (3) creation of small islands through deposition or the like. These three control techniques are discussed, in turn, below.

Heating PVD-deposited Ag above the percolation level will aid in making a continuous network of Ag nano-wires, as can be appreciated from the somewhat similar technologies involved in the FIG. 2A-4C examples. A wide range of temperatures can be used in connection with certain example embodiments, and the temperature may be between 200 degrees C. and 800 degrees C. In certain example embodiments, temperatures of 200-350 degrees C. may be used, whereas other embodiments may use temperatures of 580-780 degrees C. (e.g., 600-650 degrees C.). Heating times may be fairly short such as, for example, less than or equal to about 10 minutes, less than or equal to about 5 minutes, less than or equal to about 3 minutes, less than or equal to about 1 minute, and sometimes less than or equal to about 30 seconds. It will be appreciated that higher temperatures with shorter heating times and lower temperatures with higher heating times may be more advantageous compared to, for example, higher temperature and longer time process conditions, as the former may enable a broader range of substrate materials to be used, may reduce the likelihood of the silver being over-oxidized or otherwise damaged, etc. In certain example embodiments, the 200-350 degrees C. temperatures may be compatible with room-temperature sputtering and/or heat strengthening techniques, which may be used in-line with the Ag nano-mesh formation. In certain example embodiments, the 580-780 degrees C. temperatures may be compatible with thermal temperating techniques, which may be used in-line with the Ag nano-mesh formation. Although heating (e.g., using an oven) is provided as one example, it will be appreciated that the Ag material may be energized in this and/or other ways. For example, the Ag material may be energized using flash heating, infrared (IR) heating (e.g., using IR lamps in an array under which the material passes, using a two-dimensional of IR lamps, and/or the like), microwave exposure, and/or the like. Lasers rastering over the surface also may be used in these and/or other respects.

With respect to base layer composition and/or adjustments, it will be appreciated that different base materials may have different surface energies that change the wetting and/or de-wetting behavior(s) of the silver deposited thereon. Thus, certain example embodiments may include an underlayer or underlayers that have surface energies compatible with Ag growth and the desired de-wetting. Underlayer materials may include a silicon-inclusive layer (e.g., silicon oxide, silicon nitride, silicon oxynitride), titanium oxide (e.g., TiO₂ or other suitable stoichiometry), zinc oxide (e.g., optionally doped with aluminum), tin oxide (e.g., SnO₂ or other suitable stoichiometry), Ni and/or Cr (e.g., NiCr) or an oxide thereof, Ni and/or Ti (e.g., NiTi) or an oxide thereof, etc. In certain example embodiments, a layer comprising zinc oxide may be provided directly under and contacting the Ag so as to provide a smooth layer for good crystal growth. In certain example embodiments, a silicon-inclusive layer, a layer comprising titanium oxide, and a layer comprising zinc oxide may be provided under the Ag, in this order, so as to provide for desirable optical properties. The silicon-inclusive layer may help serve as a barrier layer, e.g., reducing the likelihood of sodium migration from the substrate into the thin film layer(s) deposited thereon during formation of subsequent thin film layers, creation of the nano-mesh, and/or optional heat treatment. The layer comprising titanium oxide may serve as a high index of refraction layer, improving optics of the coating, e.g., by reducing reflectivity/increasing transmission. The layer comprising zinc oxide may form a smooth layer on which the Ag can be at least initially deposited and thus promote the growth of a good layer comprising Ag. Layers comprising NbOx, ZrOx, and/or the like also may be formed directly under and contacting the Ag so as to facilitate the Ag de-wetting, in certain example embodiments. Small islands (of the above-listed and/or other materials) may in some instances be formed, e.g., with respect to at least the uppermost layer on which the Ag is to be formed and/or with respect to the Ag itself These small islands (e.g., of or including Zn or ZnOx) may in some instances act as nodes for the continuous silver film to adhere to during the hole growth phase. For instance, the Ag forming the nano-mesh may preferentially adhere to these small islands, and holes may be more likely to develop in areas where the islands absent.

A number of different techniques can be used in order to condition the surface on which the Ag mesh is to be formed and, thus, provide for base layer composition adjustments, facilitation of island formation, and/or the like. In certain example embodiments, a laser or other energy source may be used to introduce heat onto a substrate, raster a surface on which the mesh is to be formed, and/or the like. The laser or energy source may create or compensate for localized non-uniformities in heat, adjust surface roughness (and thereby alter contact angle and/or surface energy), etc. The type of laser used to increase temperature may be based on, for example, how it interacts with the substrate (or layers on the substrate) of choice, e.g., in order to provide for good temperature control. The laser focus size and/or shape, as well as the wavelengths, may be selected on this basis in certain example embodiments. The thermal conductivity of the surface(s) being heated also may be taken into account. For instance, the more thermally conductive the surface(s) being heated, the more finely sized (smaller) the laser may be, to provide for fine adjustments. In certain example embodiments, the entire substrate may be pre-heated (e.g., using a furnace or oven) and a laser may be used thereafter to create or compensate for localized hot-spots and/or cool-spots, rough areas, etc. In this regard, depending on the implementation, it may be desirable to create a uniform surface to be coated or a non-uniform surface to be coated (e.g., in terms of temperature, roughness, and/or the like). In such instances, a first heating stage may be used to precondition the surface, and a laser or other energy source may be used to increase the temperature in detected cool spots, create a flatter and/or more level surface (e.g., by removing peaks and/or valleys), etc. When a non-uniform surface is desired, the non-uniformities may be random or pseudo-random to help create the randomized mesh through de-wetting. In such instances, a first heating stage may be used to precondition the surface, and a laser or other energy source may be used to increase the temperature to create hot spots and/or a roughness profile in a desired configuration (which may or may not be random in different instances). Furthermore, in certain example embodiments, the desired configuration of the hot spots and/or roughness profile may be in registration with where islands are to be formed, e.g., such that islands preferentially form where hot spots and/or rougher surfaces are created. The structure of the nano-mesh may be influenced in these and/or other manners. As noted above, the desired configuration may he uniform, random, or pseudo-random, e.g., depending on the desired characteristics of the nano-mesh and whether further processing will be implemented. Fractal patterns may be used in certain example embodiments. In certain example embodiments, conditioning the substrate to have a desired non-uniform hot spot pattern and/or roughness profile may be used to obviate the need for any post nano-mesh formation patterning. In other example embodiments, conditioning the substrate to have a desired uniform temperature and roughness profile may be used to provide for a more uniform and expected formation of a nano-mesh that is easier to pattern, once it has been formed. Similar to the description above, it will be appreciated that the surface may be energized using laser heating and/or other ways. For example, the surface may be energized using flash heating, IR heating, microwave exposure, and/or the like. Pre-heating and/or the like also may be used to condition the surface.

Metal island formation may be accomplished using the techniques of application Ser. No. 15/051,900 filed on Feb. 24, 2016, and/or application Ser. No. 15/051,927 filed on Feb. 24, 2016, the entire contents of each of which are hereby incorporated herein by reference.

Following heat treatment, one or more overcoat layers may be added. These overcoat layers may be useful in increasing the film robustness, providing desirable optical properties, and/or the like. Suitable overcoat materials may include, for example, layers comprising Ni and/or Cr (e.g., NiCr) or an oxide thereof, layers comprising Ni and/or Ti (e.g., NiTi) or an oxide thereof, a zirconium-inclusive layer (e.g., zirconium oxide), a silicon-inclusive layer (e.g., silicon oxide, silicon nitride, silicon oxynitride), and/or the like. In certain example embodiments, one or more overcoat layers may be formed to provide a flatter and/or more level surface, which may be advantageous in certain applications.

Using the techniques of certain example embodiments is advantageous in that a high conductivity and high transmissivity coating can be obtained. That is, the use of Ag imparts excellent conductivity, as Ag is known to provide good sheet resistance properties. However, because of the many pores, the transmission is still high, even though a bulk Ag coating otherwise would be expected to have a lower transmission. Using silver also provides cost advantages compared to gold and some other materials.

In certain example embodiments, the silver thickness will be 5-150 nm thick. Suitable coatings may be 7-11 nm thick in some examples, which approaches the minimum workable thickness for silver where too many discontinuous islands form and where conductivity will drop too low. In other examples, 40-120 nm thickness may be used. Increasing the thickness too much could result in transmission dropping below desirable levels, even in the presence of pores. In certain example embodiments, sheet resistance may be between 10-200 ohms/square. In some devices, a 10-30 ohms/square sheet resistance may be desirable. Visible transmission preferably is greater than 70%, more preferably greater than 75%, and sometimes greater than 85-90%, e.g., when measured on 3 mm thick clear glass.

In one commercially effective example that may be used with a projected capacitive touch panel, an Ag mesh coating is 40-120nm thick, with a sheet resistance of 50-130 ohms/square. The visible transmission is 77-87%, and the surface area of the Ag network is 5-15%, whereas the surface area of open holes is 85-95%.

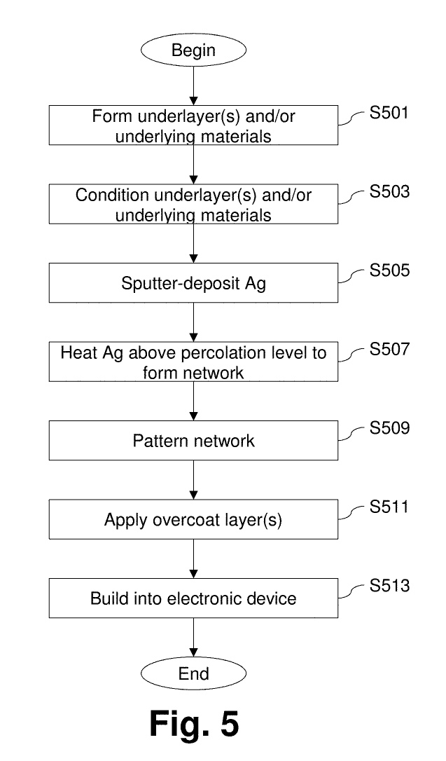

FIG. 5 is a flowchart showing an example process for forming a silver nano-mesh usable in connection with certain example embodiments. In step S501, one or more underlayers and/or underlying materials (e.g., a series of islands) may be formed on a substrate (e.g., a glass substrate or the like). The underlayer(s) and/or underlying material(s) is/are conditioned in step S503, e.g., via heating the coated substrate in its entirety (e.g., in a furnace or convection source) and/or applying localized heating (e.g., from a laser or other energy source) to create uniformities and/or non-uniformities in the temperature and/or surface conditions (e.g., surface energies) across the surface to be coated. Silver is sputter deposited in step S505. Once deposited, the silver is heated above the percolation level to form a random network of wires or the like in step S507. The network may be patterned in step S509, e.g., to form TFTs, capacitors, and/or the like. Laser etching, photolithographic techniques, and/or the like may be used for this purpose. One or more overcoat layers may be applied over the Ag network in step S511, e.g., to protect the silver and/or provide desired optical properties. The thus-formed intermediate article may be built into an electronic device in step S513 (e.g., a touch panel, display device, or the like).

Although certain example embodiments have mentioned de-wetting of the Ag, it will be appreciated that a more generalized de-wetting of the Ag, or the spreading parameter S, is contemplated herein. The de-wetting thus may be partial or complete in different example embodiments. In some cases, the silver may completely de-wet in some places and only partially de-wet in other places. With respect to the spreading parameter S, if the spreading parameter of Ag is greater than 0, total wetting occurs. When S<0, partial wetting or agglomeration will occur. As is known by those skilled in the art, S=γSG−(γSL+γLG), where γSG is the surface tension at the solid-gas interface, γSL is the surface tension at the solid-liquid interface, and γLG is the surface tension at the liquid-gas interface.

The electrodes described herein may be used in the electronic devices described in application Ser. No. 15/215,908 filed on Jul. 21, 2016; application Ser. No. 15/146,270 filed on May 4, 2016; application Ser. No. 62/364,918 filed on Jul. 21, 2016; and/or U.S. Pat. No. 9,354,755. For example, the electrodes may be used in a capacitive touch panel (e.g., a projected capacitive touch panel) or the like. Furthermore, the Ag nano-mesh described herein may take the place of any of the conductive layers (e.g., Ag layers) described in these patent documents, or the entire conducive coatings, in some instances. The entire contents of each of these documents is hereby incorporated herein by reference.

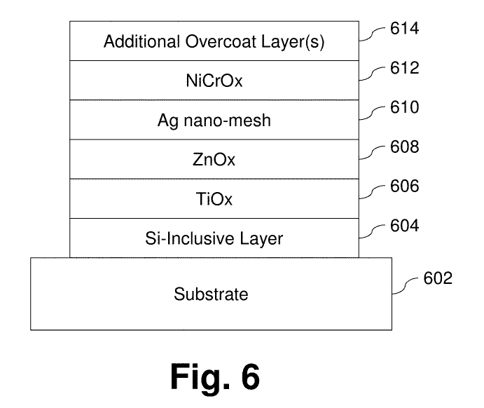

FIG. 6 is a cross-sectional view of a coated article made in accordance with certain example embodiments. A substrate 602 supports a plurality of thin film layers including a silicon-inclusive layer 604 and one or more layers formed thereon for optical purposes (e.g., a layer comprising TiOx 606). A layer comprising ZnOx 608 may provide good adhesion for the Ag to be deposited thereon. An Ag nano-mesh 610 is formed on the layer comprising ZnOx 608. In certain example embodiments, the Ag nano-mesh 610 is formed directly over and contacting the layer comprising ZnOx 608. In certain example embodiments, a metal island layer may be interposed between the layer comprising ZnOx 608 and the Ag nano-mesh 610, e.g., providing sites for the preferential formation of Ag during the de-wetting and associated processes. In certain example embodiments, the layer comprising ZnOx 608 may be conditioned to provide for the preferential formation of Ag during the de-wetting and associated processes. The Ag nano-mesh 610 may be patterned using a laser, photolithographically, or otherwise, e.g., to form desired electrode or other structures. A layer comprising Ni, Cr, Ti, and/or or the like may be provided over the Ag nano-mesh 610. For instance, in the FIG. 6 example, a layer comprising NiCrOx 612 is provided over and contacting the Ag nano-mesh 610. This layer may help protect the Ag in the nano-mesh from being oxidized and/or otherwise damaged during other processing steps. One or more additional overcoats 614 may be provided as uppermost layer(s) in the layer stack, e.g., for protecting the Ag nano-mesh 610, forming insulating areas, etc. In certain example embodiments, the additional overcoat(s) 614 may be flattening and/or levelling with respect to the underlying surfaces and, for example, with respect to height deviations caused by or related to the Ag nano-mesh 610 and/or roughness-adjusted layers thereunder.

The terms “heat treatment” and “heat treating” as used herein mean heating the article to a temperature sufficient to achieve thermal tempering and/or heat strengthening of the glass inclusive article. This definition includes, for example, heating a coated article in an oven or furnace at a temperature of at least about 550 degrees C., more preferably at least about 580 degrees C., more preferably at least about 600 degrees C., more preferably at least about 620 degrees C., and most preferably at least about 650 degrees C. for a sufficient period to allow tempering and/or heat strengthening. This may be for at least about two minutes, or up to about 10 minutes, in certain example embodiments.

As used herein, the terms “on,” “supported by,” and the like should not be interpreted to mean that two elements are directly adjacent to one another unless explicitly stated. In other words, a first layer may be said to be “on” or “supported by” a second layer, even if there are one or more layers therebetween.

In certain example embodiments, a method of making an electronic device is provided. A thin film underlayer is formed, directly or indirectly, on a substrate. Silver is sputter-deposited directly on and in contact with the underlayer. The sputter-deposited silver is heated to a temperature and for a time sufficient to cause the silver to at least partially de-wet and form a nano-mesh comprising silver wires and pores. The underlayer has a surface energy facilitating the at least partial de-wetting of the silver and the formation of the nano-mesh. The substrate with the nano-mesh formed thereon is built into the electronic device.

In addition to the features of the previous paragraph, in certain example embodiments, the nano-mesh may be etched to form an electrode for the electronic device.

In addition to the features of either of the two previous paragraphs, in certain example embodiments, the surface energy of at least a portion of the underlayer may be modified prior to the sputter-depositing of the silver.

In addition to the features of the previous paragraph, in certain example embodiments, the modifying of the surface energy may promote surface energy uniformity across the underlayer.

In addition to the features of either of the two previous paragraphs, in certain example embodiments, the modifying of the surface energy may promote surface energy non-uniformity across the underlayer.

In addition to the features of the previous paragraph, in certain example embodiments, the non-uniformity may be at least pseudo-random.

In addition to the features of any of the four previous paragraphs, in certain example embodiments, the modifying of the surface energy may be performed in first and second stages, e.g., with the first stage preceding the second stage, the first stage promoting surface energy uniformity across the underlayer and the second stage promoting surface energy non-uniformity across the underlayer.

In addition to the features of any of the five previous paragraphs, in certain example embodiments, the modifying may be performed (at least in part) using a laser.

In addition to the features of any of the six previous paragraphs, in certain example embodiments, the modifying may be performed (at least in part) using a flash heat source, infrared heat source, and/or microwave heat source.

In addition to the features of any of the seven previous paragraphs, in certain example embodiments, a surface roughness of at least a portion of the underlayer may be adjusted prior to the sputter-depositing of the silver.

In addition to the features of the previous paragraph, in certain example embodiments, the adjusting of the surface roughness may either promote uniformity or non-uniformity, or first uniformity and then non-uniformity, in surface roughness across the underlayer.

In addition to the features of any of the 11 previous paragraphs, in certain example embodiments, a plurality of metal islands may be formed, directly or indirectly, on the substrate prior to the sputter-depositing of the silver.

In addition to the features of the previous paragraph, in certain example embodiments, the silver may at least partially de-wet and preferentially re-form in registration with the metal islands.

In addition to the features of either of the two previous paragraphs, in certain example embodiments, the metal islands may be formed over the underlayer, e.g., such that the silver at least initially is sputtered deposited directly onto and in contact with (a) the metal islands in areas where the metal islands are present, and (b) the underlayer in other areas where the metal islands are riot present.

In addition to the features of any of the 14 previous paragraphs, in certain example embodiments, an overcoat maybe provided over and contacting the nano-mesh.

In addition to the features of any of the 15 previous paragraphs, in certain example embodiments, the underlayer may comprise Zn, Nb, Zr, and/or an oxide thereof.

In addition to the features of any of the 16 previous paragraphs, in certain example embodiments, the nano-mesh may have a sheet resistance of 50-130 ohms/square, and/or a porosity of 85-95%, and and/or a visible transmission of 77-87%.

The electronic device of any of the 17 previous paragraphs may be formed and/or may be or include a touch panel in different example embodiments,

While the invention has been described in connection with what is presently considered to be the most practical and preferred embodiment, it is to be understood that the invention is not to be limited to the disclosed embodiment, but on the contrary, is intended to cover various modifications and equivalent arrangements included within the spirit and scope of the appended claims.

What is claimed is:

1. A method of making an electronic device, the method comprising:
forming a thin film underlayer, directly or indirectly, on a substrate;
sputter depositing silver directly on and in contact with the underlayer;
heating the sputter-deposited silver to a temperature and for a time sufficient to cause the silver to at least partially de-wet and form a nano-mesh comprising silver wires and pores, the underlayer having a surface energy facilitating the at least partial de-wetting of the silver and the formation of the nano-mesh; and
building the substrate with the nano-mesh formed thereon into the electronic device.

2. The method of claim 1, further comprising etching the nano-mesh to form an electrode for the electronic device.

3. The method of claim 1, further comprising modifying the surface energy of at least a portion of the underlayer prior to the sputter-depositing of the silver.

4. The method of claim 3, wherein the modifying of the surface energy promotes surface energy uniformity across the underlayer.

5. The method of claim 3, wherein the modifying of the surface energy promotes surface energy non-uniformity across the underlayer.

6. The method of claim 5, wherein the non-uniformity is at least pseudo-random.

7. The method of claim 3, wherein the modifying of the surface energy is performed in first and second stages, the first stage preceding the second stage, the first stage promoting surface energy uniformity across the underlayer and the second stage promoting surface energy non-uniformity across the underlayer.

8. The method of claim 3, wherein the modifying is performed using a laser.

9. The method of claim 3, wherein the modifying is performed using a flash heat source, infrared heat source, and/or microwave heat source.

10. The method of claim 3, further comprising adjusting a surface roughness of at least a portion of the underlayer prior to the sputter-depositing of the silver.

11. The method of claim 10, wherein the adjusting of the surface roughness promotes uniformity in surface roughness across the underlayer.

12. The method of claim 10, wherein the adjusting of the surface roughness promotes non-uniformity in surface roughness across the underlayer.

13. The method of claim 1, further comprising forming a plurality of metal islands, directly or indirectly, on the substrate prior to the sputter-depositing of the silver.

14. The method of claim 13, wherein the silver at least partially de-wets and preferentially re-forms in registration with the metal islands.

15. The method of claim 13, wherein the metal islands are formed over the underlayer.

16. The method of claim 13, wherein the metal islands are formed over the underlayer such that the silver at least initially is sputtered deposited directly onto and in contact with (a) the metal islands in areas where the metal islands are present, and (b) the underlayer in other areas where the metal islands are not present.

17. The method of claim 1, wherein the underlayer comprises ZnOx.

18. The method of claim 1, wherein the underlayer comprises Nb, Zr, and/or an oxide thereof.

19. The method of claim 1, wherein the nano-mesh has a sheet resistance of 50-130 ohms/square, a porosity of 85-95%, and a visible transmission of 77-87%.

20. The method of claim 1, wherein the electronic device includes a touch panel.

21. An electronic device made by the method of claim 1.

22. A touch panel made by the method of claim 20.
